(19) United States
(12) Patent Application Publication
(10) Pub. No.: US 2002/0187420 A1
(43) Pub. Date: Dec. 12, 2002

(54) Novel copolymers and photoresist compositions

(75) Inventors: George G. Barclay, Jefferson, MA (US); Robert J. Kavanagh, Natick, MA (US)

Correspondence Address: EDWARDS & ANGELL, LLP, Dike, Bronstein, Roberts & Cushman IP Group, P.O. Box 9169, Boston, MA, 02209, US

(73) Assignee: Shipley Company, L.L.C., Marlborough, MA

(21) Appl. No.: 10/082,769

(22) Filed: Feb. 25, 2002

Related U.S. Application Data
(60) Provisional application No. 60/271,404, filed on Feb. 25, 2001.

(51) Int. Cl. G03F 7/004

(52) U.S. Cl. 430/270.1; 430/910; 430/905; 430/326; 526/319

(57) ABSTRACT

The present invention includes polymers and photoresist compositions that comprise the polymers as a resin binder component. Polymers of the invention contain a hydroxyadamantyl functionality. Photoresists of the invention include chemically-amplified positive-acting resists that can be effectively imaged at short wavelengths such as sub-200 nm, particularly 193 nm.

### BACKGROUND OF THE INVENTION

1. Field of the Invention

The present invention relates to new polymers and use of such polymers as a resin component for photoresist compositions, particularly chemically-amplified positive-acting resists that can be effectively imaged at short wavelengths such as sub-200 nm, particularly 193 nm. Resins of the invention comprise a hydroxyadamantyl moiety.

2. Background

Photoresists are photosensitive films used for transfer of images to a substrate. A coating layer of a photoresist is formed on a substrate and the photoresist layer is then exposed through a photomask to a source of activating radiation. The photomask has areas that are opaque to activating radiation and other areas that are transparent to activating radiation. Exposure to activating radiation provides a photoinduced chemical transformation of the photoresist coating to thereby transfer the pattern of the photomask to the photoresist-coated substrate. Following exposure, the photoresist is developed to provide a relief image that permits selective processing of a substrate.

A photoresist can be either positive-acting or negative-acting. For most negative-acting photoresists, those coating layer portions that are exposed to activating radiation polymerize or crosslink in a reaction between a photoactive compound and polymerizable reagents of the photoresist composition. Consequently, the exposed coating portions are rendered less soluble in a developer solution than unexposed portions. For a positive-acting photoresist, exposed portions are rendered more soluble in a developer solution while areas not exposed remain comparatively less developer soluble. Photoresist compositions are described in Deforest, Photoresist Materials and Processes, McGraw Hill Book Company, New York, ch. 2, 1975 and by Moreau, Semiconductor Lithography, Principles, Practices and Materials, Plenum Press, New York, ch. 2 and 4.

More recently, chemically-amplified-type resists have been increasingly employed, particularly for formation of sub-micron images and other high performance applications. Such photoresists may be negative-acting or positive-acting and generally include many crosslinking events (in the case of a negative-acting resist) or deprotection reactions (in the case of a positive-acting resist) per unit of photogenerated acid. In the case of positive chemically-amplified resists, certain cationic photoinitiators have been used to induce cleavage of certain “blocking” groups pendant from a photoresist binder, or cleavage of certain groups that comprise a photoresist binder backbone. See, for example, U.S. Pat. Nos. 5,075,199; 4,968,581; 4,883,740; 4,810,613; and 4,491,628, and Canadian Patent Application 2,001,384. Upon cleavage of the blocking group through exposure of a coating layer of such a resist, a polar functional group is formed, e.g., carboxyl or imide, which results in different solubility characteristics in exposed and unexposed areas of the resist coating layer. See also R. D. Allen et al., Proceedings of SPIE, 2724:334-343 (1996); and P. Trefonas et al. Proceedings of the 11th International Conference on Photopolymers (Soc. Of Plastics Engineers), pp 44-58 (Oct. 6, 1997).

While currently available photoresists are suitable for many applications, current resists also can exhibit significant shortcomings, particularly in high performance applications such as formation of highly resolved sub-half micron and sub-quarter micron features.

Consequently, interest has increased in photoresists that can be photoimaged with short wavelength radiation, including exposure radiation of about 250 nm or less, or even about 200 nm or less, such as wavelengths of about 248 run (provided by KrF laser) or 193 nm provided by an ArF exposure tool). See European Published Application EP915382A2. Use of such short exposure wavelengths can enable formation of smaller features. Accordingly, a photoresist that yields well-resolved images upon 248 nm or 193 nm exposure could enable formation of extremely small (e.g. sub-0.25 μm) features that respond to constant industry demands for smaller dimension circuit patterns, e.g. to provide greater circuit density and enhanced device performance.

However, many current photoresists are generally designed for imaging at relatively higher wavelengths, such as G-line (436 nm) and I-line (365 nm) are generally unsuitable for imaging at short wavelengths such as sub-200nm. Even shorter wavelength resists, such as those effective at 248 nm exposures, also are generally unsuitable for sub-200 nm exposures, such as 193 nm imaging.

More specifically, current photoresists can be highly opaque to extremely short exposure wavelengths such as 193 nm, thereby resulting in poorly resolved images.

It thus would be desirable to have new photoresist compositions, particularly resist compositions that can be imaged at short wavelengths such as sub-200 nm exposure wavelengths, particularly 193 nm.

### SUMMARY OF THE INVENTION

We have now found novel polymers and photoresist compositions that comprise the polymers as a resin binder component. The photoresist compositions of the invention can provide highly resolved relief images upon exposure to extremely short wavelengths, particularly sub-200 nm wavelengths such as 193 nm.

Polymers of the invention contain an adamantly group that has a hydroxy substituent (i.e. an hydroxyadamantyl group). As used herein, the term “hydroxyadamantyl group” means an adamantyl group that has a hydroxy ring substituent.

Preferably, the adamantly group is a moiety of an acrylate group, and can be polymerized to provide repeat units such as those of the following formula I:

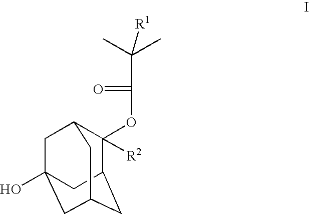

wherein R¹ is hydrogen or C₁₋₁₆alkyl preferably hydrogen or methyl, and R² is hydrogen or C₁₋₂₀alkyl, preferably hydrogen or methyl.

Preferred polymers of the invention are copolymers or higher order polymers such as terpolymers, tetrapolymers or pentapolymers. A wide variety of repeat units may be incorporated into the polymer. For instance, the polymers may contain 1) a variety of photoacid-labile moieties, particularly a photoacid-labile group that contains an alicyclic group, e.g. a photoacid-labile ester such as a polymerized alkyl acrylate or alkylmethacrylate preferably where the alkyl group is an alicyclic such as adamantyl, fencyl, and the like; 2) a group that contains a polymerized electron-deficient monomer that is non-photoacid-labile, or at least less reactive (e.g. 2 or 3 times less reactive) to photoacid than units 1), such as an ethylene unsaturated ketone or di-ketone, e.g. an anhydride such as maleic anhydride, itaconic anhydride, citrionic anhydride; amides such as maleimide; esters, particularly lactones; etc.; and 3) a group that includes a polymerized cyclic olefin moiety (i.e. where the olefinic group is polymerized along the polymer backbone to provide a fused carbon alicyclic group) such as an optionally substituted norbomene group.

Preferred polymers include those that contain a polymerized first norbornene repeat unit, and a polymerized second norbomene repeat unit, where the second unit is distinct from the first unit. For instance, the first norbornene repeat unit can be unsubstituted, and the second norbornene repeat unit can have one or more non-hydrogen repeat units. Alternatively, the first and second norbomene repeat units each can have one or more non-hydrogen ring substituents, but where the non-hydrogen substituent(s) of the first norbomene repeat unit is different than the non-hydrogen substituent(s) of the second norbomene repeat unit.

Thus, in a preferred aspect of the invention, polymers are provided that contain at least two distinct polymerized norbomene repeat units. Preferably such polymers also will contain photoacid-labile groups, either as a substituent of one or both of the two distinct norbornene repeat units, or as a polymer repeat unit separate from the norbornene units. For example, photoacid-labile acrylate units may be present together with the two or more distinct polymerized norbornene repeat units.

In a further aspect of the invention, polymers of the invention are provided that contain at least two distinct units that each have photoacid labile groups. For instance, a polymer may contain the adamantyl group as a component of an ester group such as shown in above formula I, particularly where R² is alkyl to provide a quaternary carbon that promotes the photoinduced deprotection reaction.

Polymers of the invention also may contain units in addition to the above groups. For example, polymers of the invention also may contain nitrile such as provided by polymerization of methacrylonitrile and acrylonitrile. Additional contrast enhancing groups also may be present in polymers of the invention, such as groups provided by polymerization of methacrylic acid, acrylic acid, and such acids protected as photoacid labile esters, e.g. as provided by reaction of ethoxyethyl methacrylate, t-butoxy methacrylate, t-butylmethacrylate and the like.

Polymers of the invention are preferably employed in photoresists imaged at 193 nm, and thus preferably will be substantially free of any phenyl or other aromatic groups. For example, preferred polymers contain less than about 5 mole percent aromatic groups, more preferably less than about 1 or 2 mole percent aromatic groups, more preferably less than about 0.1, 0.02, 0.04 and 0.08 mole percent aromatic groups and still more preferably less than about 0.01 mole percent aromatic groups. Particularly preferred polymers are completely free of aromatic groups. Aromatic groups can be highly absorbing of sub-200 nm radiation and thus are undesirable for polymers used in photoresists imaged with such short wavelength radiation.

The invention also provides methods for forming relief images, including methods for forming a highly resolved relief image such as a pattern of lines where each line has essentially vertical sidewalls and a line width of about 0.40 microns or less, and even a width of about 0.25, 0.20 or 0.16 microns or less. The invention further provides articles of manufacture comprising substrates such as a microelectronic wafer substrate or liquid crystal display or other flat panel display substrate having coated thereon a polymer, photoresist or resist relief image of the invention.

Other aspects of the invention are disclosed infra.

### DETAILED DESCRIPTION OF THE INVENTION

Preferred polymers of the invention comprise a hydroxyadamantyl group and one or more repeat units that comprise a photoacid-labile group.

Preferred polymers contain a photoacid labile ester group with a tertiary alicyclic hydrocarbon ester moiety that is preferably other than adamantyl. Preferred tertiary alicyclic hydrocarbon ester moieties are polycyclic groups such ethylfencyl group or a tricyclo decanyl moiety. References herein to a “tertiary alicyclic ester group” or other similar term indicate that a tertiary alicyclic ring carbon is covalently linked to the ester oxygen, i.e. —C(═O)O—TR where T is a tertiary ring carbon of alicyclic group R. In at least many cases, preferably a tertiary ring carbon of the alicyclic moiety will be covalently linked to the ester oxygen, such as exemplified by the below depicted specifically preferred polymers. However, the tertiary carbon linked to the ester oxygen also can be exocyclic to the alicyclic ring, typically where the alicyclic ring is one of the substituents of the exocyclic tertiary carbon (see for instance the substituted cyclohexyl group below having a molecular volume of 161 Å³). Typically, the tertiary carbon linked to the ester oxygen will be substituted by the alicyclic ring itself, and/or one, two or three alkyl groups having 1 to about 12 carbons, more typically 1 to about 8 carbons, even more typically 1, 2, 3 or 4 carbons. The alicyclic group also suitably will not contain aromatic substitution. The alicyclic groups may be suitably monocyclic, or polycyclic, particularly bicyclic or tricyclic groups.

Polymers of the invention also may contain photoacid-labile groups that do not contain an alicyclic moiety. For example, polymers of the invention may contain photoacid-labile ester units, such as a photoacid-labile alkyl ester. Generally, the carboxyl oxygen (i.e. the carboxyl oxygen as underlined as follows: —C(═O)O) of the photoacid-labile ester will be covalently linked to quaternary carbon. References herein to a “quaternary” carbon indicate the carbon atom has four non-hydrogen substituents (i.e. CRR¹R²R³ where R, R¹, R² and R³ are each the same or different and each is other than hydrogen). See, for instance, Morrison and Boyd, Organic Chemistry, particularly at page 85 (3^{rd} ed., Allyn and Bacon), for a discussion of the term quaternary. More particularly, preferred non-cyclic photoacid labile groups include t-butyl esters and more highly branched systems where the ester group comprises an optionally substituted alkyl moiety having about 5 or preferably 6 or more carbon atoms, with at least two branched carbon atoms, i.e. at least two secondary, tertiary or quaternary carbon atoms. Suitable alkyl moieties include those that have one, two or more tertiary carbon atoms, and/or one, two or more quaternary carbons. References herein to a “secondary” carbon indicate the carbon atom has two non-hydrogen substituents (i.e. CH₂RR¹ where R and R¹ are the same or different and each is other than hydrogen); references herein to a “tertiary” carbon indicate the carbon atom has three non-hydrogen substituents (i.e. CHRR¹R² where R, R¹ and R² are the same or different and each is other than hydrogen). See, again, Morrison and Boyd, Organic Chemistry, particularly at page 85 (3^{rd} ed., Allyn and Bacon), for a discussion of those terms secondary and tertiary. It also should be understood that references herein to “alkyl” are inclusive of linked or branched carbon chains such as alkylidene, alkylene and the like.

Some preferred highly branched photoacid-labile esters include the following:

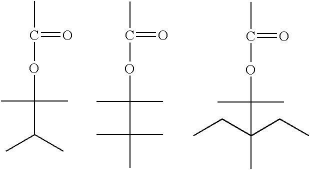

Polymers of the invention may contain units in addition to the alkyl esters units described above. For example, polymers may contain additional photoacid-labile groups such as pendant esters such as those of the formula —WC(═O)OR⁵, wherein W is a linker such as a chemical bond, an alkylene particularly C₁₋₃ alkylene, or carbocyclic aryl such as phenyl, or aryloxy such as phenoxy, and R⁵ is a suitable ester moiety such as an optionally substituted alkyl (including cycloalkyl) suitably having from 1 to about 20 carbons, more preferably about 4 to about 12 carbons, but without a noncyclic or single ring alkyl group having 5 or more carbons and two or more secondary, tertiary or quaternary carbons; optionally substituted alkenyl (including cycloalkenyl) group suitably having from 2 to about 20 carbons, more preferably about 4 to about 12 carbons; optionally substituted alkynyl group suitably having from 2 to about 20 carbons, more preferably about 4 to about 12 carbons; optionally substituted alkoxy group suitably having from 1 to about 20 carbons, more preferably 2 to about 12 carbons; or a heteroalicyclic group that contains one or more N, O or S atoms and one or more rings having from 4 to about 8 ring members such as tetrahydrofuranyl, thienyl, tetrahydropyranyl, morpholino and the like. Specifically preferred R⁵ groups include e.g. t-butyl, tetrahydropyran, ethoxyethyl, or an alicyclic group including bridged groups such as such as adamantyl including 2-methyl-2-adamantyl, norbomyl, isobornyl and the like. Polymers of the invention also may contain aromatic units, such as polymerized vinylphenol, styrene units and the like. Such aromatic units are particularly suitable for polymers used in photoresists imaged at 248 nm. However, as discussed above, for even shorter wavelength imaging, such as 193 nm, preferably a polymer is substantially, essentially or completely free of aromatic units.

Polymers imaged at 248 nm or other higher wavelengths may suitably comprise phenolic units, such as provide by co-polymerization of a vinylphenol.

Specifically preferred polymers of the invention include the following, with specifically preferred molar ratios of the respective polymer units shown to the right of the depicted polymer:

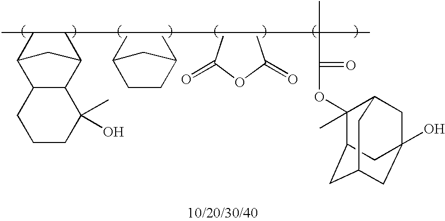

Additional preferred polymers of the invention comprise an adamantyl acrylate (without hydroxy substitution) such as methyl adamantyl acrylate and/or β-lactone acrylate or methacrylate in combination with a hydroxyadamantyl group. Such additional repeat units may suitably be of the following formula II and III:

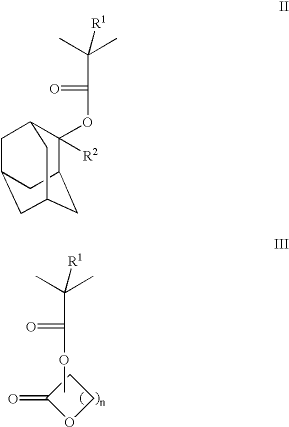

where R¹ and R² are the same as defined above for formula I, and n is an integer of from 1 to 5.

Specifically preferred polymers of the invention include the following five terpolymers (i.e. 1) through 5) below) where the mole percents are expressed as total polymer units:

1) terpolymer consisting of units of a) formula II groups where R¹═R²═CH₃, 40 mole percent; b) formula II groups where R¹═CH₃, n═2, 40 mole percent; c) formula III groups R¹═CH₃, R²═H, 20 mole percent.

2) terpolymer consisting of units of a) formula II groups where R¹═R²═CH₃, 30 mole percent; b) formula II groups where R¹═CH₃, n═2, 30 mole percent; c) formula III groups R¹═CH₃, R²═H, 40 mole percent.

3) terpolymer consisting of units of a) formula II groups where R¹═R²═CH₃, 60 mole percent; b) formula II groups where R¹═CH₃, n═2, 30 mole percent; c) formula III groups R¹═CH₃, R²═H, 10 mole percent.

4) terpolymer consisting of units of a) formula II groups where R¹═R²═CH₃, 50 mole percent; b) formula II groups where R¹═CH₃, n═2, 30 mole percent; c) formula III groups R¹═CH₃, R²═H, 20 mole percent.

5) terpolymer consisting of units of a) formula II groups where R¹═R²═CH₃, 30 mole percent; b) formula II groups where R¹═CH₃, n═2, 50 mole percent; c) formula II groups R¹═CH₃, R²═H, 20 mole percent.

Polymers of the invention can be prepared by a variety of methods. One suitable method is an addition reaction which may include free radical polymerization, e.g., by reaction of selected monomers to provide the various units as discussed above in the presence of a radical initiator under an inert atmosphere (e.g., N₂ or argon) and at elevated temperatures such as about 70° C. or greater, although reaction temperatures may vary depending on the reactivity of the particular reagents employed and the boiling point of the reaction solvent (if a solvent is employed). Suitable reaction solvents include e.g. tetrahydrofuran, ethyl lactate and the Eke. Suitable reaction temperatures for any particular system can be readily determined empirically by those skilled in the art based on the present disclosure. A variety of free radical initiators may be employed. For example, azo compounds may be employed such as azo-bis-2,4-dimethylpentanenitrile. Peroxides, peresters, peracids and persulfates also could be employed.

Hydroxyadamantylacrylate monomers are commercially available.

As discussed, various moieties may be optionally substituted, including groups of formulae I. A “substituted” substituent may be substituted at one or more available positions, typically 1, 2, or 3 positions by one or more suitable groups such as e.g. halogen (particularly F, Cl or Br); C₁₋₈ alkyl; C₁₋₈ alkoxy; C₂₋₈ alkenyl; C₂₋₈ alkynyl; hydroxyl; alkanoyl such as a C₁₋₆ alkanoyl e.g. acyl and the like; etc

Preferably a polymer of the invention will have a weight average molecular weight (Mw) of about 800 or 1,000 to about 100,000, more preferably about 2,000 to about 30,000, still more preferably from about 2,000 to 15,000 or 20,000, with a molecular weight distribution (Mw/Mn) of about 3 or less, more preferably a molecular weight distribution of about 2 or less. Molecular weights (either Mw or Mn) of the polymers of the invention are suitably determined by gel permeation chromatography.

Polymers of the invention used in photoresist formulations should contain a sufficient amount of photogenerated acid labile ester groups to enable formation of resist relief images as desired. For instance, suitable amount of such acid labile ester groups will be at least 1 mole percent of total units of the polymer, more preferably about 2 to 40, 50, 60 or 70 mole percent, still more typically about 3 to 30, 40, 50, 60 or 70 mole percent of total polymer units.

As discussed above, the polymers of the invention are highly useful as a resin binder component in photoresist compositions, particularly chemically-amplified positive resists. Photoresists of the invention in general comprise a photoactive component and a resin binder component that comprises a polymer as described above.

The resin binder component should be used in an amount sufficient to render a coating layer of the resist developable with an aqueous alkaline developer.

The resist compositions of the invention also comprise a photoacid generator (i.e. “PAG”) that is suitably employed in an amount sufficient to generate a latent image in a coating layer of the resist upon exposure to activating radiation. Preferred PAGs for imaging at 193 nm and 248 nm imaging include imidosulfonates such as compounds of the following formula:

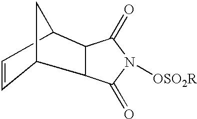

wherein R is camphor, adamantane, alkyl (e.g. C₁₋₁₂ alkyl) and perfluoroalkyl such as perfluoro(C₁₋₁₂alkyl), particularly perfluorooctanesulfonate, perfluorononanesulfonate and the like. A specifically preferred PAG is N-[(perfluorooctanesulfonyl)oxy]-5-norbornene-2,3-dicarboximide.

Sulfonate compounds are also suitable PAGs, particularly sulfonate salts. Two suitable agents for 193 nm and 248 nm imaging are the following PAGS 1 and 2:

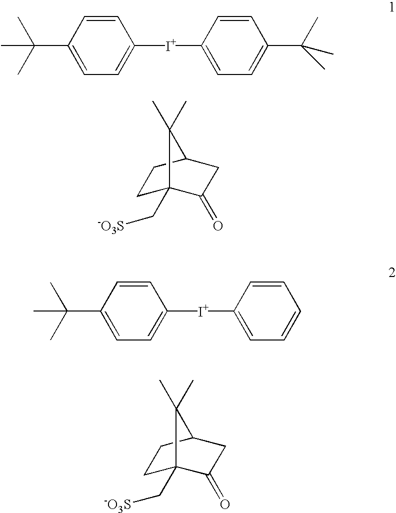

Such sulfonate compounds can be prepared as disclosed in European Patent Application 96118111.2 (publication number 0783136), which details the synthesis of above PAG 1.

Also suitable are the above two iodonium compounds complexed with anions other than the above-depicted camphorsulfonate groups. In particular, preferred anions include those of the formula RSO₃—where R is adamantane, alkyl (e.g. C₁₋₁₂ alkyl) and perfluoroalkyl such as perfluoro (C ₁₁₂alkyl), particularly perfluorooctanesulfonate, perfluorobutanesulfonate and the like.

Other known PAGS also may be employed in the resists of the invention. Particularly for 193 nm imaging, generally preferred are PAGS that do not contain aromatic groups, such as the above-mentioned imidosulfonates, in order to provide enhanced transparency.

A preferred optional additive of resists of the invention is an added base, particularly tetrabutylammonium hydroxide (TBAH), or tetrabutylammonium lactate, which can enhance resolution of a developed resist relief image. For resists imaged at 193 nm, a preferred added base is a hindered amine such as diazabicyclo undecene or diazabicyclononene. The added base is suitably used in relatively small amounts, e.g. about 0.03 to 5 percent by weight relative to the total solids.

Photoresists of the invention also may contain other optional materials. For example, other optional additives include anti-striation agents, plasticizers, speed enhancers, etc. Such optional additives typically will be present in minor concentrations in a photoresist composition except for fillers and dyes which may be present in relatively large concentrations, e.g., in amounts of from about 5 to 30 percent by weight of the total weight of a resist's dry components.

The resists of the invention can be readily prepared by those skilled in the art. For example, a photoresist composition of the invention can be prepared by dissolving the components of the photoresist in a suitable solvent such as, for example, ethyl lactate, ethylene glycol monomethyl ether, ethylene glycol monomethyl ether acetate, propylene glycol monomethyl ether; propylene glycol monomethyl ether acetate and 3-ethoxyethyl propionate. Typically, the solids content of the composition varies between about 5 and 35 percent by weight of the total weight of the photoresist composition. The resin binder and photoactive components should be present in amounts sufficient to provide a film coating layer and formation of good quality latent and relief images. See the examples which follow for exemplary preferred amounts of resist components.

The compositions of the invention are used in accordance with generally known procedures. The liquid coating compositions of the invention are applied to a substrate such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning.

The resist compositions of the invention are suitably applied to substrates conventionally used in processes involving coating with photoresists. For example, the composition may be applied over silicon wafers or silicon wafers coated with silicon dioxide for the production of microprocessors and other integrated circuit components. Aluminum-aluminum oxide, gallium arsenide, ceramic, quartz, copper, glass substrates and the like are also suitably employed.

Following coating of the photoresist onto a surface, it is dried by heating to remove the solvent until preferably the photoresist coating is tack free. Thereafter, it is imaged through a mask in conventional manner. The exposure is sufficient to effectively activate the photoactive component of the photoresist system to produce a patterned image in the resist coating layer and, more specifically, the exposure energy typically ranges from about 1 to 100 mJ/cm², dependent upon the exposure tool and the components of the photoresist composition.

As discussed above, coating layers of the resist compositions of the invention are preferably photoactivated by a short exposure wavelength, particularly a sub-300 and sub-200 nm exposure wavelength. As discussed above, 193 nm is a particularly preferred exposure wavelength. 157 nm is another preferred exposure wavelength for resists of the invention. However, the resist compositions of the invention also may be suitably imaged at higher wavelengths. For example, a resin of the invention can be formulated with an appropriate PAG and a sensitizer if needed and imaged at higher wavelengths such as about 248 nm or 365 nm.

Following exposure, the film layer of the composition is preferably baked at temperatures ranging from about 70° C. to about 160° C. Thereafter, the film is developed. The exposed resist film is rendered positive working by employing a polar developer, preferably an aqueous based developer such as quaternary ammonium hydroxide solutions such as a tetra-alkyl ammonium hydroxide solution; various amine solutions preferably a 0.26 N tetramethylammonium hydroxide, such as ethyl amine, n-propyl amine, diethyl amine, di-n-propyl amine, triethyl amine, or methyldiethyl amine; alcohol amines such as diethanol amine or triethanol amine; cyclic amines such as pyrrole, pyridine, etc. In general, development is in accordance with procedures recognized in the art.

Following development of the photoresist coating over the substrate, the developed substrate may be selectively processed on those areas bared of resist, for example by chemically etching or plating substrate areas bared of resist in accordance with procedures known in the art. For the manufacture of microelectronic substrates, e.g., the manufacture of silicon dioxide wafers, suitable etchants include a gas etchant, e.g. a halogen plasma etchant such as a chlorine or fluorine-based etchant such a Cl₂ or CF₄/CHF₃ etchant applied as a plasma stream. After such processing, resist may be removed from the processed substrate using known stripping procedures.

All documents mentioned herein are incorporated herein by reference. The following non-limiting examples are illustrative of the invention.

### EXAMPLE 1

### Polymer Synthesis

A mixture of 2-methyladamantanyl methacrylate (15.00 g, 0.064 mol), maleic anhydride (4.71 g, 0.048 mol), norbomene (3.01 g, 0.032 mole), hydroxyadamanylmethacrylate (3.07 g, 0.016 mol), and V601 (1.11 g, 3% mole of total monomers) in 25.79 mL (1/1═monomer/solvent) of inhibitor free tetrahydrofuran is placed in a round-bottomed flask. After stirring for 5 minutes, the flask is put into a pre-heated oil bath. The reaction mixture is stirred at this temperature until the reaction is substantially complete. After cooling, THF is added to this flask. The polymer is isolated such as by precipitation into 1.5 L of hexane/IPA (1/1, % wt.).

### EXAMPLE 2

### Photoresist Preparation and Lithographic Processing

A photoresist of the invention is prepared by mixing the following components with amount expressed as weight percents based on total weight of the resist composition:

| Resist components | Amount (wt. %) |
|---|---|
| Resin binder | 15 |
| Photoacid generator | 4 |
| Ethyl lactate | 81 |

The resin binder is the polymer of Example 1 above. The photoacid generator is di-(4-t-butylphenyl)iodonium (+/−)-10-camphor sulfonate (PAG 1 above). Those resin and PAG components are admixed in the ethyl lactate solvent.

The formulated resist composition is spin coated onto HMDS vapor primed 4 inch silicon wafers and softbaked via a vacuum hotplate at 90° C. for 60 seconds. The resist coating layer is exposed through a photomask at 193 nm, and then the exposed coating layers are post-exposure baked (PEB) at about 110° C. The coated wafers are then treated with 0.26N aqueous tetramethylammonium hydroxide solution to develop the imaged resist layer and provide a relief image.

The foregoing description of the invention is merely illustrative thereof, and it is understood that variations and modification can be made without departing from the spirit or scope of the invention as set forth in the following claims.

What is claimed is:

1. A photoresist composition comprising a photoactive component and a resin that comprises a hydroxyadamantyl unit.

2. A photoresist of claim 1 wherein the hydroxyadamantyl unit is provided by polymerization of an acrylate or methacrylate.

3. A photoresist of claim 1 or 2 wherein the resin comprises photoacid-labile groups.

4. A photoresist of claim 3 wherein the resin comprises an alicyclic group in addition to the hydroxyadamantyl.

5. A photoresist of claim 2 or 3 wherein the resin comprises a photoacid-labile ester group.

6. A photoresist of any one of claims 1 through 5 wherein the resin comprises a polymerized cyclic olefin.

7. A photoresist of any one of claims 1 through 6 wherein the resin comprises a polymerized monomer comprising ethylene unsaturated carbonyl or di-carbonyl.

8. A photoresist of any one of claims 1 through 7 wherein the resin is a terpolymer.

9. A photoresist of any one of claims 1 through 8 wherein the resin is a tetrapolymer.

10. The photoresist of any one of claims 1 through 9 wherein the polymer further comprises one or more units selected from the group consisting of an acid; nitrile; an anhydride; a lactone; or a photoacid labile group that contains a leaving group that has other than an alicyclic moiety.

11. The photoresist of any one of claims 1 through 11 wherein the polymer is substantially of aromatic groups.

12. A method of forming a positive photoresist relief image, comprising:
(a) applying a coating layer of a photoresist of any one of claims 1 through 11 on a substrate; and
(b) exposing and developing the photoresist layer to yield a relief image.

13. The method of claim 12 wherein the photoresist layer is exposed with radiation having a wavelength of less than about 200 nm.

14. The method of claim 12 wherein the photoresist layer is exposed with radiation having a wavelength of about 193 nm.

15. An article of manufacture comprising a microelectronic wafer substrate or flat panel display substrate having coated thereon a layer of the photoresist composition of any one of claims 1 through 11.

16. A resin that comprises a hydroxyadamantyl unit.

17. A resin of claim 16 wherein the hydroxyadamantyl unit is provided by polymerization of an acrylate or methacrylate.

18. A resin of claim 16 or 17 wherein the resin comprises photoacid-labile groups.

19. A resin of claim 18 wherein the resin comprises an alicyclic group in addition to adamantyl.

20. A resin of claim 18 or 19 wherein the resin comprises a photoacid-labile ester group.

21. A resin of any one of claims 16 through 20 wherein the resin comprises a polymerized cyclic olefin.

22. A resin of any one of claims 16 through 21 wherein the resin is a terpolymner.

23. A resin of any one of claims 16 through 22 wherein the resin is a tetrapolymer.

24. A resin of any one of claims 16 through 23 wherein the polymer further comprises one or more units selected from the group consisting of an acid; nitrile; an anhydride; a lactone; or a photoacid labile group that contains a leaving group that has other than an alicyclic moiety.

25. A resin of any one of claims 16 through 24 wherein the polymer is substantially of aromatic groups.
